(19) United States
(12) Patent Application Publication
(10) Pub. No.: US 2026/0047155 A1
(43) Pub. Date: Feb. 12, 2026

(54) PLANAR DEVICE AND METHOD FOR MANUFACTURING SAME

(71) Applicant: Shanghai Huali Integrated Circuit Corporation, Shanghai (CN)

(72) Inventor: Wenying Weng, Shanghai (CN)

(73) Assignee: Shanghai Huali Integrated Circuit Corporation, Shanghai (CN)

(21) Appl. No.: 19/060,991

(22) Filed: Feb. 24, 2025

(30) Foreign Application Priority Data
Aug. 12, 2024 (CN) 202411103674.4

(51) Int. Cl. H10D 62/10; H01L 21/02; H10D 30/01; H10D 30/60; H10D 62/17; H10D 62/832

(52) U.S. Cl. CPC H10D 62/115; H10D 30/027; H10D 30/60; H10D 62/364; H01L 21/02271; H10D 62/832

(57) ABSTRACT

The disclosure discloses a planar device, in a formation region of the planar device, the first and second semiconductor epitaxial layers on the semiconductor substrate have a patterned structure including: both the second semiconductor epitaxial layer and the first semiconductor epitaxial layer in the source-drain formation region being removed, and a first trench being formed. The first trench is filled with a first dielectric layer. A void structure is formed in the gate region after the first semiconductor epitaxial layer is removed. A third semiconductor epitaxial layer is formed on the top surface and an exposed side surface of the second semiconductor epitaxial layer, and constitutes a top epitaxial layer together with the second semiconductor epitaxial layer. A gate structure is formed on a top surface of the top epitaxial layer at the top of the void structure. The disclosure also discloses a method for manufacturing a planar device.

### CROSS-REFERENCE TO RELATED APPLICATIONS

This application claims priority to Chinese patent application No. 202411103674.4, filed on Aug. 12, 2024, the disclosure of which is incorporated herein by reference in its entirety.

### TECHNICAL FIELD

The present disclosure relates to the field of semiconductor integrated circuit manufacturing, and in particular to a planar device. The present disclosure also relates to a method for manufacturing a planar device.

### BACKGROUND

FIG. 1 is a schematic diagram of a cross-sectional structure of an existing planar device. The existing planar device includes:
a semiconductor substrate 101, such as a silicon substrate.
A gate structure is formed on a top surface of the semiconductor substrate 101.
The gate structure includes a gate dielectric layer 102 and a polysilicon gate 103 stacked in sequence.
A source region 104 and a drain region 105 are formed in the semiconductor substrate 101 at two sides of the gate structure.
A channel region is located between the source region 104 and the drain region 105 and covered by the gate structure.
The polysilicon gate 103 is connected to a gate, the source region 104 is connected to a source, and the drain region 105 is connected to a drain.

When a voltage between the gate and the source, i.e., a gate-source voltage, is greater than or equal to a threshold voltage, a conductive channel composed of carriers of an inversion layer is formed on a surface region of the channel region, so that conduction between the source region 104 and the drain region 105 is implemented through the conductive channel and thus a source-drain current is formed.

However, as the process node shrinks continuously, the length of the channel region shrinks is scaled down continuously, making it likely to form a large leakage path 106 in the semiconductor substrate 101 away from the gate structure. A leakage current of the leakage path 106 does pass through the conductive channel, and therefore is a current uncontrolled by the gate structure. The presence of the leakage path 106 may degrade the performance of the device.

In an existing method, the use of an expensive silicon on insulator (SOI) substrate is usually required to eliminate the leakage path 106, which causes a high process cost.

### BRIEF SUMMARY

According to some embodiments in this application, a planar device provided by the present disclosure is formed on a semiconductor substrate, where a first semiconductor epitaxial layer and a second semiconductor epitaxial layer are formed sequentially on a top surface of the semiconductor substrate; a material of the first semiconductor epitaxial layer is different from a material of the semiconductor substrate, and the material of the first semiconductor epitaxial layer is different from a material of the second semiconductor epitaxial layer.

A formation region of the planar device includes a gate formation region and a source-drain formation region at two sides of the gate formation region.

In the formation region of the planar device, the first semiconductor epitaxial layer and the second semiconductor epitaxial layer have a patterned structure.

The patterned structure includes: both the second semiconductor epitaxial layer and the first semiconductor epitaxial layer in the source-drain formation region being removed, and a first trench being formed; the second semiconductor epitaxial layer in the gate formation region being retained, and the first semiconductor epitaxial layer in the gate formation region being removed.

The first trench is filled with a first dielectric layer, a top surface of the first dielectric layer is located between a top surface and a bottom surface of the second semiconductor epitaxial layer, and a side surface of the second semiconductor epitaxial layer above the top surface of the first dielectric layer is exposed.

A void structure is formed in the gate region after the first semiconductor epitaxial layer is removed, a side surface of the void structure is defined by a side surface of the first dielectric layer by means of self-alignment, a top surface of the void structure is defined by the bottom surface of the second semiconductor epitaxial layer by means of self-alignment, and a bottom surface of the void structure is defined by a top surface of the semiconductor substrate by means of self-alignment.

A third semiconductor epitaxial layer is formed on the top surface and the exposed side surface of the second semiconductor epitaxial layer, and the third semiconductor epitaxial layer extends from the exposed side surface of the second semiconductor epitaxial layer to the top surface of the first dielectric layer.

The second semiconductor epitaxial layer and the third semiconductor epitaxial layer constitute a top epitaxial layer, and a top surface of the top epitaxial layer is a planarized surface.

A gate structure is formed on the top surface of the top epitaxial layer at the top of the void structure, and the top epitaxial layer covered by the gate structure serves as a channel region.

A source region and a drain region are formed in the top epitaxial layer at two side of the gate structure.

In some cases, the material of the second semiconductor epitaxial layer is the same as the material of the semiconductor substrate; and a material of the third semiconductor epitaxial layer is the same as the material of the second semiconductor epitaxial layer.

In some cases, the material of the second semiconductor epitaxial layer includes Si or SiGe.

In some cases, the material of the first semiconductor epitaxial layer includes Si or SiGe.

In some cases, the material of the second semiconductor epitaxial layer is Si and the material of the first semiconductor epitaxial layer is SiGe; alternatively, the material of the second semiconductor epitaxial layer is SiGe and the material of the first semiconductor epitaxial layer is Si.

In some cases, a material of the first dielectric layer includes an oxide layer.

In some cases, the first dielectric layer is a flowable chemical vapor deposition (FCVD) oxide layer.

In some cases, the top surface of the top epitaxial layer is higher than the top surface of the second semiconductor epitaxial layer; alternatively, the top surface of the top epitaxial layer is located below or is flush with the top surface of the second semiconductor epitaxial layer, and the third semiconductor epitaxial layer on the top surface of the second semiconductor epitaxial layer is removed by means of planarization.

In order to solve the above technical problem, the method for manufacturing a planar device provided by the present disclosure includes the following steps:
step I: providing a semiconductor substrate, where a first semiconductor epitaxial layer and a second semiconductor epitaxial layer are formed sequentially on a top surface of the semiconductor substrate;
a material of the first semiconductor epitaxial layer is different from a material of the semiconductor substrate, and the material of the first semiconductor epitaxial layer is different from a material of the second semiconductor epitaxial layer;
step II: performing patterned etching on the first semiconductor epitaxial layer and second semiconductor epitaxial layer, including:
opening a source-drain formation region of the planar device and covering a gate formation region of the planar device, where the source-drain formation region is located at two sides of the gate formation region; and
performing etching to remove both the second semiconductor epitaxial layer and the first semiconductor epitaxial layer in the source-drain formation region, form a first trench, and retain both the second semiconductor epitaxial layer and the first semiconductor epitaxial layer in the gate formation region;
step III: filling the first trench with a first dielectric layer, where a top surface of the first dielectric layer is located between a top surface and a bottom surface of the second semiconductor epitaxial layer, and a side surface of the second semiconductor epitaxial layer above the top surface of the first dielectric layer is exposed;
step IV: performing first selective epitaxial growth on the top surface and the exposed side surface of the second semiconductor epitaxial layer to form a third semiconductor epitaxial layer,
where the third semiconductor epitaxial layer is formed on the top surface and the exposed side surface of the second semiconductor epitaxial layer, and the third semiconductor epitaxial layer extends from the exposed side surface of the second semiconductor epitaxial layer to the top surface of the first dielectric layer;
the second semiconductor epitaxial layer and the third semiconductor epitaxial layer constitute a top epitaxial layer;
step V: planarizing the top epitaxial layer by means of a first chemical mechanical polishing process, so that a top surface of the top epitaxial layer is a planarized surface;
step VI: performing selective etching to remove, by means of self-alignment, the first semiconductor epitaxial layer retained in the gate formation region and to form a void structure after the first semiconductor epitaxial layer is removed, where a side surface of the void structure is defined by a side surface of the first dielectric layer by means of self-alignment, a top surface of the void structure is defined by the bottom surface of the second semiconductor epitaxial layer by means of self-alignment, and a bottom surface of the void structure is defined by a top surface of the semiconductor substrate by means of self-alignment;
step VII: forming a gate structure on the top surface of the top epitaxial layer at the top of the void structure, where the top epitaxial layer covered by the gate structure serves as a channel region; and
step VIII: performing source-drain implantation to form a source region and a drain region in the top epitaxial layer at two sides of the gate structure respectively.

In some cases, the material of the second semiconductor epitaxial layer is the same as the material of the semiconductor substrate; and a material of the third semiconductor epitaxial layer is the same as the material of the second semiconductor epitaxial layer.

In some cases, the material of the second semiconductor epitaxial layer includes Si or SiGe.

In some cases, the material of the first semiconductor epitaxial layer includes Si or SiGe.

In some cases, the material of the second semiconductor epitaxial layer is Si and the material of the first semiconductor epitaxial layer is SiGe; alternatively, the material of the second semiconductor epitaxial layer is SiGe and the material of the first semiconductor epitaxial layer is Si.

In some cases, a material of the first dielectric layer includes an oxide layer.

In some cases, the first dielectric layer is formed by means of an FCVD process.

In some cases, step III includes the following sub-steps:

growing the first dielectric layer by means of the FCVD process, where the first dielectric layer fully fills the first trench and extends outside the first trench;

performing a 0th chemical mechanical polishing process to planarize the first dielectric layer, where the 0th chemical mechanical polishing process removes the first dielectric layer outside the first trench and makes the top surface of the first dielectric layer in the first trench flush with the top surface of the second semiconductor epitaxial layer; and

etching back the first dielectric layer such that the top surface of the first dielectric layer is lowered as being between the top surface and the bottom surface of the second semiconductor epitaxial layer.

In some cases, after the first chemical mechanical polishing process is completed, the top surface of the top epitaxial layer is higher than the top surface of the second semiconductor epitaxial layer; alternatively, after the first chemical mechanical polishing process is completed, the top surface of the top epitaxial layer is located below or is flush with the top surface of the second semiconductor epitaxial layer, and the third semiconductor epitaxial layer on the top surface of the second semiconductor epitaxial layer is removed.

By means of the present disclosure, without the use of an SOI substrate, the full depletion channel region may be implemented directly using the semiconductor substrate. The channel region and the semiconductor substrate at the bottom are isolated from each other by the void structure, where the void structure is obtained by removing the first semiconductor epitaxial layer at the bottom of the channel region by means of self-alignment. Since the channel region and the semiconductor substrate are isolated from each other by the void structure the channel region may implement a full depletion thin-layer structure, improving the control on the channel region performed by the gate structure and thereby improving the performance of the device. Moreover, due to an isolation effect of the void structure in the present disclosure, a source-drain leakage path through the semiconductor substrate may be eliminated, thereby reducing a leakage of the device. In addition, since the use of an SOI substrate is not required in the present disclosure, the process cost may be reduced.

### BRIEF DESCRIPTION OF THE DRAWINGS

The present disclosure is further described in detail below with reference to the drawings and specific embodiments:

FIG. 1 is a schematic diagram of a cross-sectional structure of an existing planar device;

FIG. 2A is a schematic diagram of a cross-sectional structure of a planar device according to embodiments of the present disclosure;

FIG. 2B is a schematic diagram of a cross-sectional structure of a semiconductor substrate of the planar device according to embodiments of the present disclosure; and

FIGS. 3A-3F are schematic diagrams of cross-sectional structures of a device in steps of a method for manufacturing a planar device according to embodiments of the present disclosure.

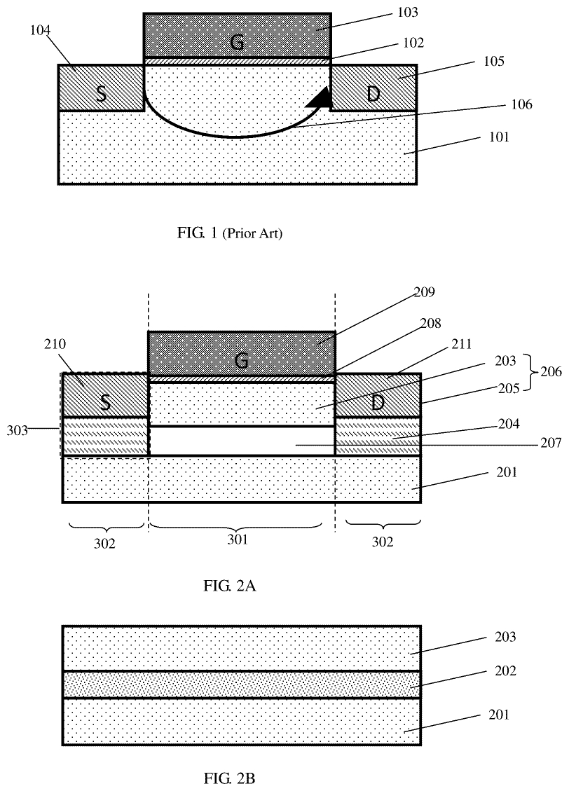

### DETAILED DESCRIPTION OF THE DISCLOSURE

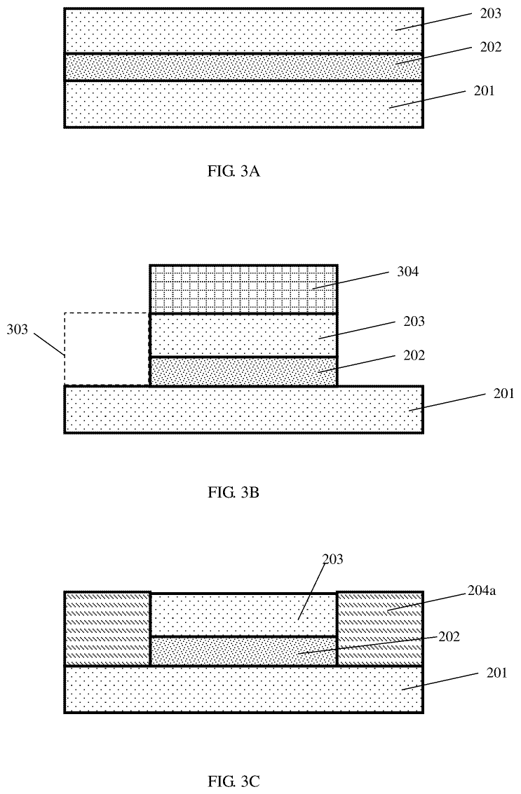

FIG. 2A is a schematic diagram of a cross-sectional structure of a planar device according to embodiments of the present disclosure. FIG. 2B is a schematic diagram of a cross-sectional structure of a semiconductor substrate 201 of the planar device according to embodiments of the present disclosure. The planar device of the embodiments of the present disclosure is formed on the semiconductor substrate 201. Referring to FIG. 2B, a first semiconductor epitaxial layer 202 and a second semiconductor epitaxial layer 203 are formed sequentially on a top surface of the semiconductor substrate 201; a material of the first semiconductor epitaxial layer 202 is different from a material of the semiconductor substrate 201, and the material of the first semiconductor epitaxial layer 202 is different from a material of the second semiconductor epitaxial layer 203.

FIG. 2A shows only a schematic structural diagram of a formation region of the planar device. Referring to FIG. 2A, the formation region of the planar device includes a gate formation region 301 and a source-drain formation region 302 at two sides of the gate formation region 301. In FIG. 2A, the gate formation region 301 is located between two dashed lines, with the source-drain formation region 302 at the two sides thereof presenting a symmetrical structure and being represented with the same label 302.

In the formation region of the planar device, the first semiconductor epitaxial layer 202 and the second semiconductor epitaxial layer 203 have a patterned structure.

The patterned structure includes: both the second semiconductor epitaxial layer 203 and the first semiconductor epitaxial layer 202 in the source-drain formation region 302 being removed, and a first trench 303 being formed; the second semiconductor epitaxial layer 203 in the gate formation region 301 being retained, and the first semiconductor epitaxial layer 202 in the gate formation region 301 being removed.

The first trench 303 is filled with a first dielectric layer 204, where a top surface of the first dielectric layer 204 is located between a top surface and a bottom surface of the second semiconductor epitaxial layer 203, and a side surface of the second semiconductor epitaxial layer 203 above the top surface of the first dielectric layer 204 is exposed.

In the embodiments of the present disclosure, a material of the first dielectric layer 204 includes an oxide layer. In some example embodiments, the first dielectric layer 204 is an FCVD oxide layer. The FCVD oxide layer is an oxide layer formed by means of an FCVD process, and the use of the FCVD oxide layer is conducive to improving the quality of filling the first trench 303.

A void structure 207 is formed in the gate region after the first semiconductor epitaxial layer 202 is removed, a side surface of the void structure 207 is defined by a side surface of the first dielectric layer 204 by means of self-alignment, a top surface of the void structure 207 is defined by the bottom surface of the second semiconductor epitaxial layer 203 by means of self-alignment, and a bottom surface of the void structure 207 is defined by a top surface of the semiconductor substrate 201 by means of self-alignment.

A third semiconductor epitaxial layer 205 is formed on the top surface and the exposed side surface of the second semiconductor epitaxial layer 203, and the third semiconductor epitaxial layer 205 extends from the exposed side surface of the second semiconductor epitaxial layer 203 to the top surface of the first dielectric layer 204.

The second semiconductor epitaxial layer 203 and the third semiconductor epitaxial layer 205 constitute a top epitaxial layer 206, and a top surface of the top epitaxial layer 206 is a planarized surface. In some embodiments, the top surface of the top epitaxial layer 206 is higher than the top surface of the second semiconductor epitaxial layer 203, in which case a portion of the thickness of the third semiconductor epitaxial layer 205 is retained on the top surface of the second semiconductor epitaxial layer 203. In some embodiments, the top surface of the top epitaxial layer 206 may alternatively be located below or is flush with the top surface of the second semiconductor epitaxial layer 203, in which case the third semiconductor epitaxial layer 205 on the top surface of the second semiconductor epitaxial layer 203 is removed, and in the gate formation region 301, the top epitaxial layer 206 is composed of the second semiconductor epitaxial layer 203.

A gate structure is formed on the top surface of the top epitaxial layer 206 at the top of the void structure 207, and the top epitaxial layer 206 covered by the gate structure serves as a channel region.

In the embodiments of the present disclosure, the thickness of the subsequent channel region may be adjusted by controlling the top surface of the top epitaxial layer 206. In some embodiments, the thickness of the channel region may be adjusted to implement a full depletion structure, which facilitates the control on the channel region performed by the gate structure, thereby improving the performance of the device.

In the embodiments of the present disclosure, the gate structure includes a gate dielectric layer 208 and a gate conductive material layer 209 stacked in sequence. In some specific embodiments, a material of the gate dielectric layer 208 is silicon dioxide or a high dielectric constant material. The gate conductive material layer 209 is a polysilicon gate or a metal gate.

A source region 210 and a drain region 211 are formed in the top epitaxial layer 206 at two side of the gate structure. In FIG. 2A, the gate conductive material layer 209 is represented by G, the source region 210 is represented by S, and the drain region 211 is represented by D.

It can be seen from FIG. 2A that, the channel region is a region that can be controlled by the gate structure. The void structure 207 is provided such that the semiconductor substrate 207 far away from the gate structure does not contact the channel region, thereby forming no leakage path. Accordingly, by means of the embodiments of the present disclosure, the leakage of the device may be reduced.

It can be seen from FIG. 2A that, the planar device of the embodiments of the present disclosure is actually equivalent to an FDSOI device. It can be seen from FIG. 2B that, the planar device of the embodiments of the present disclosure does not require an SOI substrate, with the direct use of the semiconductor substrate 201 of a bulk structure. Since the cost of the SOI substrate is higher, the embodiments of the present disclosure also have the advantage of a low cost.

In the embodiments of the present disclosure, the material of the second semiconductor epitaxial layer 203 is the same as the material of the semiconductor substrate 201; and a material of the third semiconductor epitaxial layer 205 is the same as the material of the second semiconductor epitaxial layer 203.

The material of the second semiconductor epitaxial layer 203 includes Si or SiGe. The material of the first semiconductor epitaxial layer 202 includes Si or SiGe. Since materials of the first semiconductor epitaxial layer 202 and the second semiconductor epitaxial layer 203 are different, there may be various combinations of the materials of the first semiconductor epitaxial layer 202 and the second semiconductor epitaxial layer 203. For example, in some embodiments, the material of the second semiconductor epitaxial layer 203 is Si and the material of the first semiconductor epitaxial layer 202 is SiGe. In other embodiments, alternatively, the material of the second semiconductor epitaxial layer 203 may be SiGe and the material of the first semiconductor epitaxial layer 202 may be Si.

It can be seen from FIG. 2A that, the planar device of the embodiments of the present disclosure is a planar device having the void structure 207 and an insulating structure, i.e., the first dielectric layer 204, which is a full depletion Si on void device.

By means of the embodiments of the present disclosure, without the use of an SOI substrate, the full depletion channel region may be implemented directly using the semiconductor substrate 201. The channel region and the semiconductor substrate 201 at the bottom are isolated from each other by the void structure 207, where the void structure 207 is obtained by removing the first semiconductor epitaxial layer 202 at the bottom of the channel region by means of self-alignment. Since the channel region and the semiconductor substrate 201 are isolated from each other by the void structure 207, the channel region may implement a full depletion thin-layer structure, improving the control on the channel region performed by the gate structure and thereby improving the performance of the device. Moreover, due to an isolation effect of the void structure 207 in the embodiments of the present disclosure, a source-drain leakage path through the semiconductor substrate 201 may be eliminated, thereby reducing a leakage of the device. In addition, since the use of an SOI substrate is not required in the embodiments of the present disclosure, the process cost may be reduced.

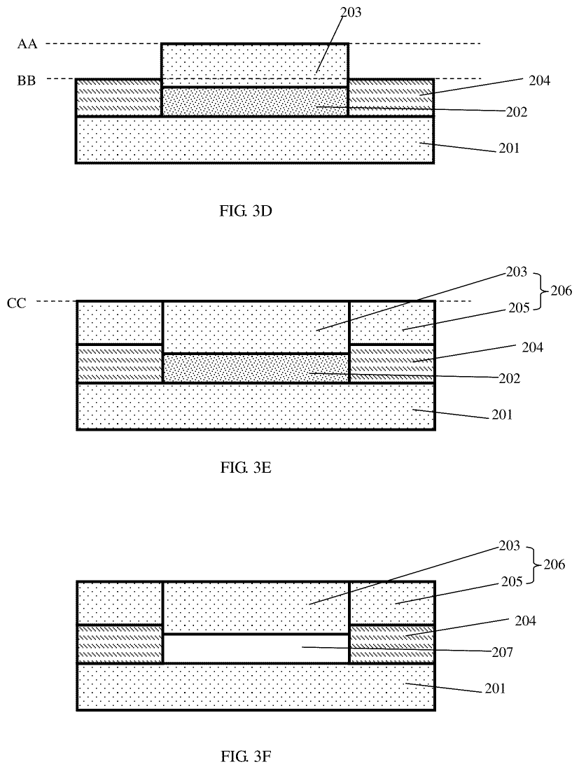

FIGS. 3A-3E are schematic diagrams of cross-sectional structures of a device in steps of a method for manufacturing a planar device according to embodiments of the present disclosure. The method for manufacturing a planar device of embodiments of the present disclosure includes the following steps.
step I: Referring to FIG. 3A, a semiconductor substrate 201 is provided, where a first semiconductor epitaxial layer 202 and a second semiconductor epitaxial layer 203 are formed sequentially on a top surface of the semiconductor substrate 201.
A material of the first semiconductor epitaxial layer 202 is different from a material of the semiconductor substrate 201, and the material of the first semiconductor epitaxial layer 202 is different from a material of the second semiconductor epitaxial layer 203.
In the method of the embodiments of the present disclosure, the material of the second semiconductor epitaxial layer 203 is the same as the material of the semiconductor substrate 201.
The material of the second semiconductor epitaxial layer 203 includes Si or SiGe. The material of the first semiconductor epitaxial layer 202 includes Si or SiGe. Since materials of the first semiconductor epitaxial layer 202 and the second semiconductor epitaxial layer 203 are different, there may be various combinations of the materials of the first semiconductor epitaxial layer 202 and the second semiconductor epitaxial layer 203. For example, in some embodiments, the material of the second semiconductor epitaxial layer is Si and the material of the first semiconductor epitaxial layer is SiGe. In other embodiments, alternatively, the material of the second semiconductor epitaxial layer may be SiGe and the material of the first semiconductor epitaxial layer may be Si.
step II: Referring to FIG. 3B, patterned etching is performed on the first semiconductor epitaxial layer 202 and second semiconductor epitaxial layer 203, including the following:
   A source-drain formation region 302 of the planar device is opened, and a gate formation region 301 of the planar device is covered, where the source-drain formation region 302 is located at two sides of the gate formation region 301. In some embodiments, a photoresist pattern 304 formed by means of a photolithography process is used to open the source-drain formation region 302 of the planar device and cover the gate formation region 301 of the planar device. In other embodiments, the photoresist pattern 304 may be replaced with a hard mask pattern.
   Etching is performed to remove both the second semiconductor epitaxial layer 203 and the first semiconductor epitaxial layer 202 in the source-drain formation region 302, form a first trench 303, and retain both the second semiconductor epitaxial layer 203 and the first semiconductor epitaxial layer 202 in the gate formation region 301.
Step III: Referring to FIG. 3D, the first trench 303 is filled with a first dielectric layer 204, where a top surface of the first dielectric layer 204 is located between a top surface and a bottom surface of the second semiconductor epitaxial layer 203, and a side surface of the second semiconductor epitaxial layer 203 above the top surface of the first dielectric layer 204 is exposed.
In the method of the embodiments of the present disclosure, a material of the first dielectric layer 204 includes an oxide layer.
In some example embodiments, the first dielectric layer 204 is formed by means of an FCVD oxide layer. Step III includes the following sub-steps:
   Referring to FIG. 3C, the first dielectric layer 204 is grown by means of the FCVD process, where the first dielectric layer 204 fully fills the first trench 303 and extends outside the first trench 303.
   Referring to FIG. 3C, a 0th chemical mechanical polishing process is performed to planarize the first dielectric layer 204, where the 0th chemical mechanical polishing process removes the first dielectric layer 204 outside the first trench 303 and makes the top surface of the first dielectric layer 204 in the first trench 303 flush with the top surface of the second semiconductor epitaxial layer 203.
   Referring to FIG. 3D, the first dielectric layer 204 is etched back such that the top surface of the first dielectric layer 204 is lowered as being between the top surface and the bottom surface of the second semiconductor epitaxial layer 203. In FIG. 3D, a dashed line AA indicates the position of the top surface of the second semiconductor epitaxial layer 203, and a dashed line BB indicates the position of the top surface of the first dielectric layer 204.
Step IV: Referring to FIG. 3E, first selective epitaxial growth is performed on the top surface and the exposed side surface of the second semiconductor epitaxial layer 203 to form a third semiconductor epitaxial layer 205.
The third semiconductor epitaxial layer 205 is formed on the top surface and the exposed side surface of the second semiconductor epitaxial layer 203, and the third semiconductor epitaxial layer 205 extends from the exposed side surface of the second semiconductor epitaxial layer 203 to the top surface of the first dielectric layer 204.
The second semiconductor epitaxial layer 203 and the third semiconductor epitaxial layer 205 constitute a top epitaxial layer 206.
In the method of the embodiments of the present disclosure, the material of the second semiconductor epitaxial layer 203 is the same as the material of the semiconductor substrate 201; and a material of the third semiconductor epitaxial layer 205 is the same as the material of the second semiconductor epitaxial layer 203. In FIG. 3E, the second semiconductor epitaxial layer 203, the semiconductor substrate 201, and the third semiconductor epitaxial layer 205 are represented with the same filling pattern.
Step V: Referring to FIG. 3E, the top epitaxial layer 206 is planarized by means of a first chemical mechanical polishing process, so that a top surface of the top epitaxial layer 206 is a planarized surface.
In the method of some embodiments, after the first chemical mechanical polishing process is completed, the top surface of the top epitaxial layer 206 is higher than the top surface of the second semiconductor epitaxial layer 203. In FIG. 3E, a dashed line CC indicates the position of the top surface of the top epitaxial layer 206. In this case, the position of the dashed line CC is higher than the position of the dashed line AA in FIG. 3D, that is a portion of the thickness of the third semiconductor epitaxial layer 205 is retained above the top surface of the second semiconductor epitaxial layer 203 in the gate formation region 301.
In the method of some embodiments, alternatively, after the first chemical mechanical polishing process is completed, the top surface of the top epitaxial layer 206 is located below or is flush with the top surface of the second semiconductor epitaxial layer 203, and the third semiconductor epitaxial layer 205 on the top surface of the second semiconductor epitaxial layer 203 is removed. In this case, the position of the dashed line CC is flush with or lower than the position of the dashed line AA in FIG. 3D, that is, the third semiconductor epitaxial layer 205 above the top surface of the second semiconductor epitaxial layer 203 in the gate formation region 301 is fully removed, and the top surface of the second semiconductor epitaxial layer 203 remains unchanged or is lowered.
In the method of the embodiments of the present disclosure, the position of the top surface of the top epitaxial layer 206 may be adjusted by adjusting a process parameter of the first chemical mechanical polishing process, so that the thickness of the subsequent channel region may be adjusted finally and the full depletion channel region may be implemented.
Step VI: Referring to FIG. 3F, selective etching is performed to remove, by means of self-alignment, the first semiconductor epitaxial layer 202 retained in the gate formation region 301 and to form a void structure 207 after the first semiconductor epitaxial layer 202 is removed, where a side surface of the void structure 207 is defined by a side surface of the first dielectric layer 204 by means of self-alignment, a top surface of the void structure 207 is defined by the bottom surface of the second semiconductor epitaxial layer 203 by means of self-alignment, and a bottom surface of the void structure 207 is defined by a top surface of the semiconductor substrate 201 by means of self-alignment.
Step VII: Referring to FIG. 2A, a gate structure is formed on the top surface of the top epitaxial layer 206 at the top of the void structure 207, where the top epitaxial layer 206 covered by the gate structure serves as a channel region.
In the method of the embodiments of the present disclosure, the gate structure includes a gate dielectric layer 208 and a gate conductive material layer 209 stacked in sequence. In some specific embodiments, a material of the gate dielectric layer 208 is silicon dioxide or a high dielectric constant material. The gate conductive material layer 209 is a polysilicon gate or a metal gate.
Step VIII: Source-drain implantation is performed to form a source region 210 and a drain region 211 in the top epitaxial layer 206 at two sides of the gate structure respectively.

The present disclosure is described in detail above through specific embodiments that, however, do not impose limitations to the present disclosure. Without departing from the principle of the present disclosure, a skilled in the art may also made many other deformations and improvements, which should also be considered as the scope of protection of the present disclosure.

What is claimed is:

1. A planar device formed on a semiconductor substrate, wherein a first semiconductor epitaxial layer and a second semiconductor epitaxial layer are formed sequentially on a top surface of the semiconductor substrate; a material of the first semiconductor epitaxial layer is different from a material of the semiconductor substrate, and the material of the first semiconductor epitaxial layer is different from a material of the second semiconductor epitaxial layer;
a formation region of the planar device comprises a gate formation region and a source-drain formation region at two sides of the gate formation region;
in the formation region of the planar device, the first semiconductor epitaxial layer and the second semiconductor epitaxial layer have a patterned structure;
the patterned structure comprises: both the second semiconductor epitaxial layer and the first semiconductor epitaxial layer in the source-drain formation region being removed, and a first trench being formed; the second semiconductor epitaxial layer in the gate formation region being retained, and the first semiconductor epitaxial layer in the gate formation region being removed;
the first trench is filled with a first dielectric layer, a top surface of the first dielectric layer is located between a top surface and a bottom surface of the second semiconductor epitaxial layer, and a side surface of the second semiconductor epitaxial layer above the top surface of the first dielectric layer is exposed;
a void structure is formed in the gate region after the first semiconductor epitaxial layer is removed, a side surface of the void structure is defined by a side surface of the first dielectric layer by means of self-alignment, a top surface of the void structure is defined by the bottom surface of the second semiconductor epitaxial layer by means of self-alignment, and a bottom surface of the void structure is defined by a top surface of the semiconductor substrate by means of self-alignment;
a third semiconductor epitaxial layer is formed on the top surface and the exposed side surface of the second semiconductor epitaxial layer, and the third semiconductor epitaxial layer extends from the exposed side surface of the second semiconductor epitaxial layer to the top surface of the first dielectric layer;
the second semiconductor epitaxial layer and the third semiconductor epitaxial layer constitute a top epitaxial layer, and a top surface of the top epitaxial layer is a planarized surface;
a gate structure is formed on the top surface of the top epitaxial layer at the top of the void structure, and the top epitaxial layer covered by the gate structure serves as a channel region; and
a source region and a drain region are formed in the top epitaxial layer at two side of the gate structure.

2. The planar device according to claim 1, wherein the material of the second semiconductor epitaxial layer is the same as the material of the semiconductor substrate; and a material of the third semiconductor epitaxial layer is the same as the material of the second semiconductor epitaxial layer.

3. The planar device according to claim 2, wherein the material of the second semiconductor epitaxial layer comprises Si or SiGe.

4. The planar device according to claim 3, wherein the material of the first semiconductor epitaxial layer comprises Si or SiGe.

5. The planar device according to claim 4, wherein the material of the second semiconductor epitaxial layer is Si and the material of the first semiconductor epitaxial layer is SiGe; or the material of the second semiconductor epitaxial layer is SiGe and the material of the first semiconductor epitaxial layer is Si.

6. The planar device according to claim 1, wherein a material of the first dielectric layer comprises an oxide layer.

7. The planar device according to claim 6, wherein the first dielectric layer is a flowable chemical vapor deposition (FCVD) oxide layer.

8. The planar device according to claim 1, wherein the top surface of the top epitaxial layer is higher than the top surface of the second semiconductor epitaxial layer; or the top surface of the top epitaxial layer is located below or is flush with the top surface of the second semiconductor epitaxial layer, and the third semiconductor epitaxial layer on the top surface of the second semiconductor epitaxial layer is removed by means of planarization.

9. A method for manufacturing a planar device, comprising the following steps:
step I: providing a semiconductor substrate, wherein a first semiconductor epitaxial layer and a second semiconductor epitaxial layer are formed sequentially on a top surface of the semiconductor substrate;
a material of the first semiconductor epitaxial layer is different from a material of the semiconductor substrate, and the material of the first semiconductor epitaxial layer is different from a material of the second semiconductor epitaxial layer;
step II: performing patterned etching on the first semiconductor epitaxial layer and second semiconductor epitaxial layer, comprising:
opening a source-drain formation region of the planar device and covering a gate formation region of the planar device, wherein the source-drain formation region is located at two sides of the gate formation region; and
performing etching to remove both the second semiconductor epitaxial layer and the first semiconductor epitaxial layer in the source-drain formation region, form a first trench, and retain both the second semiconductor epitaxial layer and the first semiconductor epitaxial layer in the gate formation region;
step III: filling the first trench with a first dielectric layer, wherein a top surface of the first dielectric layer is located between a top surface and a bottom surface of the second semiconductor epitaxial layer, and a side surface of the second semiconductor epitaxial layer above the top surface of the first dielectric layer is exposed;
step IV: performing first selective epitaxial growth on the top surface and the exposed side surface of the second semiconductor epitaxial layer to form a third semiconductor epitaxial layer,
wherein the third semiconductor epitaxial layer is formed on the top surface and the exposed side surface of the second semiconductor epitaxial layer, and the third semiconductor epitaxial layer extends from the exposed side surface of the second semiconductor epitaxial layer to the top surface of the first dielectric layer;
the second semiconductor epitaxial layer and the third semiconductor epitaxial layer constitute a top epitaxial layer;
step V: planarizing the top epitaxial layer by means of a first chemical mechanical polishing process, so that a top surface of the top epitaxial layer is a planarized surface;
step VI: performing selective etching to remove, by means of self-alignment, the first semiconductor epitaxial layer retained in the gate formation region and to form a void structure after the first semiconductor epitaxial layer is removed, wherein a side surface of the void structure is defined by a side surface of the first dielectric layer by means of self-alignment, a top surface of the void structure is defined by the bottom surface of the second semiconductor epitaxial layer by means of self-alignment, and a bottom surface of the void structure is defined by a top surface of the semiconductor substrate by means of self-alignment;
step VII: forming a gate structure on the top surface of the top epitaxial layer at the top of the void structure, wherein the top epitaxial layer covered by the gate structure serves as a channel region; and
step VIII: performing source-drain implantation to form a source region and a drain region in the top epitaxial layer at two sides of the gate structure respectively.

10. The method for manufacturing the planar device according to claim 9, wherein the material of the second semiconductor epitaxial layer is the same as the material of the semiconductor substrate; and a material of the third semiconductor epitaxial layer is the same as the material of the second semiconductor epitaxial layer.

11. The method for manufacturing the planar device according to claim 10, wherein the material of the second semiconductor epitaxial layer comprises Si or SiGe.

12. The method for manufacturing the planar device according to claim 11, wherein the material of the first semiconductor epitaxial layer comprises Si or SiGe.

13. The method for manufacturing the planar device according to claim 12, wherein the material of the second semiconductor epitaxial layer is Si and the material of the first semiconductor epitaxial layer is SiGe; or the material of the second semiconductor epitaxial layer is SiGe and the material of the first semiconductor epitaxial layer is Si.

14. The method for manufacturing the planar device according to claim 9, wherein a material of the first dielectric layer comprises an oxide layer.

15. The method for manufacturing the planar device according to claim 14, wherein the first dielectric layer is formed by means of a flowable chemical vapor deposition (FCVD) process.

16. The method for manufacturing the planar device according to claim 15, wherein step III comprises the following sub-steps:
growing the first dielectric layer by means of the FCVD process, wherein the first dielectric layer fully fills the first trench and extends outside the first trench;
performing a 0th chemical mechanical polishing process to planarize the first dielectric layer, wherein the 0th chemical mechanical polishing process removes the first dielectric layer outside the first trench and makes the top surface of the first dielectric layer in the first trench flush with the top surface of the second semiconductor epitaxial layer; and
etching back the first dielectric layer such that the top surface of the first dielectric layer is lowered as being between the top surface and the bottom surface of the second semiconductor epitaxial layer.

17. The method for manufacturing the planar device according to claim 9, wherein after the first chemical mechanical polishing process is completed, the top surface of the top epitaxial layer is higher than the top surface of the second semiconductor epitaxial layer; or after the first chemical mechanical polishing process is completed, the top surface of the top epitaxial layer is located below or is flush with the top surface of the second semiconductor epitaxial layer, and the third semiconductor epitaxial layer on the top surface of the second semiconductor epitaxial layer is removed.
